(19) United States
(12) Patent Application Publication
(10) Pub. No.: US 2006/0068729 A1
(43) Pub. Date: Mar. 30, 2006

(54) Portable device utilizing vehicle audio system for playing music of specific format

(75) Inventors: Ta-Lung Yu, Taipei (TW); Feng-Jen Ho, ChaoChou Town (TW); Hao-Chih Wei, ChungPu Hsiang (TW)

Correspondence Address: BRUCE H. TROXELL, SUITE 1404, 5205 LEESBURG PIKE, FALLS CHURCH, VA, 22041, US

(73) Assignee: Action Enterprise Co., Ltd.

(21) Appl. No.: 10/952,843

(22) Filed: Sep. 30, 2004

(51) Int. Cl. H04B 1/18; H05K 11/02

(52) U.S. Cl. 455/152.1; 455/345

(57) ABSTRACT

The invention is a portable device utilizing a vehicle audio system for playing music of specific format. The primary object of the invention is to provide a portable device capable of emitting an electromagnetic signal to shield a specific frequency of a FM radio receiver of the vehicle audio system, which is similar to co-channel interference or next-channel interference in broadcasting, so as to play music of the specific format via the vehicle audio system, the portable device comprising: an electromagnetic signal emitter, capable of converting a music format into an electromagnetic signal and emitting the same via a signal modulation device; an audio input hole, for receiving an external audio source from an audio source device and electrically connected to the electromagnetic signal emitter, being disposed at an appropriate position of the portable device; a decoder, capable of decoding a specific music format; a music format identification system, capable of making an evaluation to identify if the external audio source matches the specific format, if so, the audio source is transmitted to the electromagnetic signal emitter, if not, the audio source is being forsaken; and at least an USB port, for electrically connected to a computer storage device.

1. Field of the Invention

The present invention relates to a portable device utilizing a vehicle audio system for playing music of specific format, and more particularly, to a portable device having an external display panel capable of emitting an electromagnetic signal to shield a specific frequency of a FM radio receiver of a vehicle audio system, which is similar to co-channel interference or next-channel interference in broadcasting, so as to play MP3 music via the vehicle audio system.

2. Background of the Invention

As integrated circuit complexity has continued to increase alone with the continuing size reduction of the same, more and more integrated circuit based electronic products with multi-function have been created to keep up the requirement of market. Especially, the MP3 player of all kinds of design is the hottest electronic product in the market. The MP3 format is a music format that compresses the size of music file to extremely minimal. Compared with the un-compressed standard music format CDA used in a conventional CD player, the MP3 format only occupies a space less than one-tenth of the CDA and has almost the same music quality as the conventional CD player. Hence, the MP3 format is commonly accepted by music players currently on the market, such as CD player, VCD/DVD player, personal computer (PC), personal digital assistant (PDA), and flash player, and so on.

Considering the portability and the weighting, a flash memory player also being referred as pen drive is preferred. The weight of the pen drive commonly sold in market is averagely 30˜50 grams, and the build-in memory thereof is between 64 MB to 512 MB. As each MP3 formatted song occupies 4 MB to 6 MB of memory, therefore, at least 10 to 16 songs can be saved in a pen drive of 64 MB which is equal to a conventional CD disc can store. The pen drive capable of playing MP3 formatted music certainly is a heavyweight product in audio industry.

I Conventional pen drives sold in market usually have integrated several functions in response to marketing demand. The most common functions integrated are data storing, audio recording, MP3 playing and listening to FM radio, etc., which can meet requirements of all users. The present invention provides an innovated function to the pen drive capable of playing MP3 music that is applicable to a vehicle without CD players for broadcasting the MP3 music playing in the pen drive from the vehicle audio system, in addition, as the pen drive is playing MP3 music, the vibration caused by the vehicle while driving has no influence on the playing and without interrupt or jumping problems commonly seen in the CD player.

### SUMMARY OF THE INVENTION

The invention is a portable device utilizing a vehicle audio system for playing music of specific format. The primary object of the invention is to provide a portable device capable of emitting an electromagnetic signal to shield a specific frequency of a FM radio receiver of the vehicle audio system, which is similar to co-channel interference or next-channel interference in broadcasting, so as to play music of the specific format via the vehicle audio system and the same time avoiding the abnormal playing condition commonly seen in the conventional CD player due to vibrations of the vehicle.

Another object of the invention is to provide a portable device integrated therein a plurality of functions, including: data storage, recording, playing MP3, serving as a card reader and a FM/AM radio receiver, etc., which has the same or more functions than a pen drive sold in the market.

The third object of the invention is to provide a portable device for playing music of a specific format capable of emitting an electromagnetic signal to shield a specific frequency of a FM radio receiver of an electronic device, such as a FM radio, an acoustic system, a computer, a PDA, and a mobile phone, and so on, so as to play music of the specific format via the electronic device.

A detailed description is given in the following embodiments with reference to the accompanying drawings.

### BRIEF DESCRIPTION OF THE DRAWINGS

FIG. 1 is a block diagram showing a preferred embodiment of the present invention.

FIG. 2 is a schematic diagram showing the internal structure of a portable device according to the present invention.

### DESCRIPTION OF THE PREFERRED EMBODIMENT

The present invention can be more fully understood by reading the subsequent detailed description and examples with references made to the accompanying drawings, wherein:

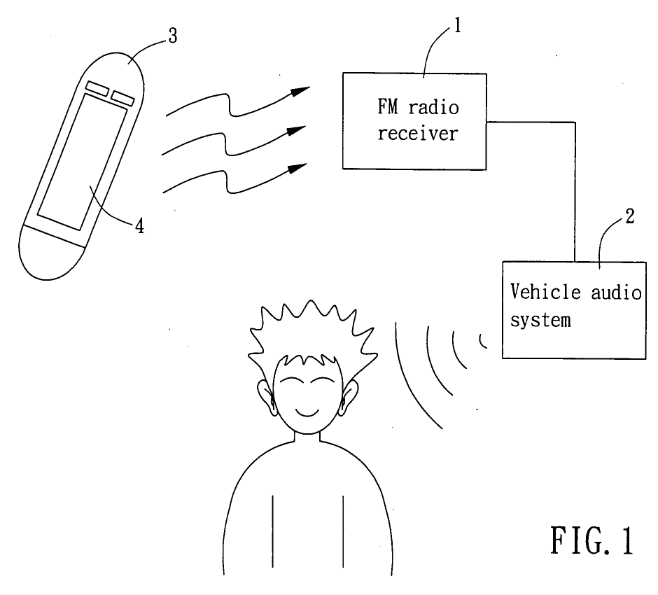

Referring to FIG. 1, a portable device 3 having a display panel 4 disposed externally capable of emitting an electromagnetic signal to shield a specific frequency of the FM radio receiver 1, which is similar to co-channel interference or next-channel interference in broadcasting, so as to play a MP3 music via the vehicle audio system. As the MP3 files are saved in a memory resided in the portable device 3 and played by a microprocessor therein, the vibration of a vehicle cannot affect the playing as happening in a conventional CD player with a laser head. It is applicable to a vehicle without CD player to serve as a CD player.

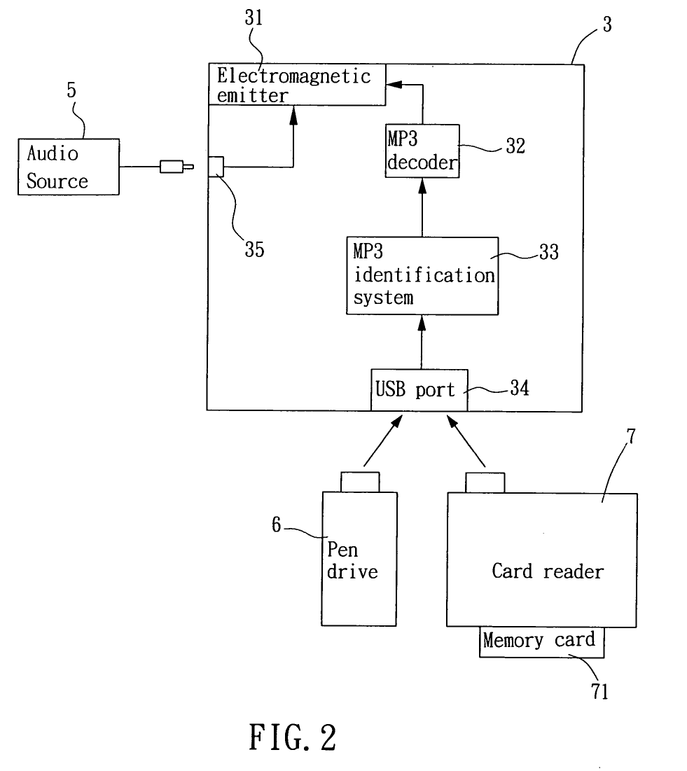

Referring to FIG. 2, the portable device 3 comprises:
an electromagnetic signal emitter 31, capable of converting a music format into an electromagnetic signal and emitting the same via a signal modulation device,
an audio input hole 36, for receiving an external audio source from an audio source device 5 and electrically connected to the electromagnetic signal emitter 31, being disposed at an appropriate position of the portable device 3;
a decoder 32, capable of decoding a specific music format;
a music format identification system 33, capable of making an evaluation to identify if the external audio source matches the specific format, if so, the audio source is transmitted to the electromagnetic signal emitter 31, if not, the audio source is being forsaken; and
at least an USB port 34, for electrically connected to a computer storage device.
wherein, the audio source device 5 (e.g. a MP3 player) is connected to the portable device 3 via the audio input hole 36 so that an electromagnetic signal is being outputted from the electromagnetic signal emitter 31 to shield a specific frequency of the FM radio receiver of a vehicle audio system 2 and play MP3 music in the specific frequency for playing MP3 formatted music using the vehicle audio system and the same time avoiding the abnormal problem caused by the vibration of the vehicle as happening in a conventional CD player.

Another application of the invention is to connect a pen drive 6 or a card reader 7 to the USB port 34 of the portable device 3. The MP3 files in the pen drive 6 or the memory card 71 in the card reader 7 is accessed by the portable device 3 via the music format identification system 33 and decoded by the decoder 32 to output a music of analog format, and the analog music signal is further being emitted to the vehicle audio system via the electromagnetic emitter 31 to function as described above.

According to FIGS. 1 and 2, the feature of the invention is the electromagnetic emitter disposed in the portable device. The electromagnetic emitter converts a music file into an electromagnetic signal and emits the same outward to shield a specific frequency of a FM radio of a vehicle audio system and play the music file using the frequency of the FM radio. Thus, it is applicable to a vehicle without CD player to serve as a CD player.

To sum up, the portable device of the present invention not only can be applied to the FM radio receiver of a vehicle audio system, but also can be applied to any common electronic device for playing music of the specific format via the electronic device, such as a FM radio, an acoustic system, a computer, a PDA, and a mobile phone, and so on.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A portable device utilizing a vehicle audio system for playing music of a specific format, capable of emitting an electromagnetic signal to shield a specific frequency of a FM radio receiver of the vehicle audio system, which is similar to co-channel interference or next-channel interference in broadcasting, so as to play music of the specific format via the vehicle audio system, comprising:
an electromagnetic signal emitter, capable of converting a music format into an electromagnetic signal and emitting the same via a signal modulation device;
an audio input hole, for receiving an external audio source from an audio source device, electrically connecting to the electromagnetic signal emitter;
a decoder, capable of decoding a specific music format;
a music format identification system, capable of making an evaluation to identify if the external audio source matches the specific format; if so, transmitting the audio source to the electromagnetic signal emitter; if not, forsaking the audio source; and
an connection interface, electrically connected to a computer storage device.

2. The portable of claim 1, wherein a display panel is disposed outside the portable device, and the display panel is activated by connecting the same with a power source and a microprocessor.

3. The portable device of claim 2, wherein the display panel is an LCD monitor.

4. The portable device of claim 1, wherein the specific music format is MP3 format.

5. The portable device of claim 1, wherein the electromagnetic signal is a radio frequency (RF) signal.

6. The portable device of claim 1, wherein the connection interface is an USB (Universal Serial) interface.

7. The portable device of claim 1, wherein the portable device is capable emitting an electromagnetic signal to shield a specific frequency of the FM radio receiver of one of the following electronic devices: a radio, an acoustic system, a computer, a personal digital assistant, a mobile phone, and so on.

8. The portable device of claim 1, wherein the computer storage device is a pen drive.

9. The portable device of claim 1, wherein the computer storage device comprises a card reader and a memory card.
